(19) United States
(12) Patent Application Publication
(10) Pub. No.: US 2025/0280509 A1
(43) Pub. Date: Sep. 4, 2025

(54) COOLING DEVICE FOR COOLING ELECTRONIC COMPONENTS

(71) Applicant: Robert Bosch GmbH, Stuttgart (DE)

(72) Inventors: Christoph Jatzek, Hechingen-Schlatt (DE); Max Florian Beck, Vaihingen An Der Enz (DE); Michael Mayer, Hohenstein (DE); Stefan Maurer, Hechingen-Schlatt (DE); Wolfram Kienle, Magstadt (DE)

(21) Appl. No.: 18/702,528

(22) PCT Filed: Nov. 15, 2022
(86) PCT No.: PCT/EP2022/081878

§ 371 Date: Apr. 18, 2024

(30) Foreign Application Priority Data
Nov. 26, 2021 (DE) 10 2021 213 356.8

(51) Int. Cl. H05K 7/20

(52) U.S. Cl. CPC H05K 7/20272; H05K 7/20927

(57) ABSTRACT

The invention relates to a cooling device (1) for cooling electronic components (2) comprising: a bottom plate (3), a top plate (4) which is a deep-drawn component with a depression (40), wherein the bottom plate (3) and the top plate (4) are arranged in such a way that a cooling duct (5) is formed between the bottom plate (3) and the top plate (4) by way of the depression (40), wherein the cooling duct (5) extends along the longitudinal direction (11) from an inlet opening (51) to an outlet opening (52), wherein a cooling fluid flow of a cooling fluid can flow through the cooling duct (5) along the longitudinal direction (10); and at least one turbulator (6) which is arranged within a turbulator section (56) of the cooling duct (5), wherein at least one tapered portion (7) of a flow cross section of the cooling duct (5) is configured upstream and/or downstream of the turbulator section (56), in order to deflect a part region, close to the edge, of the cooling fluid flow within the cooling duct (5).

### BACKGROUND

The present invention relates to a cooling device for the cooling of electronic components as well as an electronic arrangement.

Cooling devices for cooling electronic components, e.g. power modules in inverters, are known. For example, such cooling devices comprise cooling ducts through which a liquid medium can flow. In this context, it is also known to arrange turbulators in the cooling ducts in order to improve heat dissipation.

### SUMMARY

In contrast, the cooling device according to the invention is characterized by a particularly high efficiency with regard to cooling of the electronic components being cooled. According to the present invention, this is achieved by means of a cooling device for cooling electronic components comprising a bottom plate, a top plate, and at least one turbulator. The top plate is configured as a deep-drawn component which comprises a depression. In particular, the top plate is pot-shaped. The bottom plate and the top plate are arranged together so that a cooling duct is formed between the bottom plate and the top plate by the depression. The cooling duct in this case extends along a longitudinal direction from an inlet opening to an outlet opening. Preferably, when viewed at a sheet plane of the bottom plate, the cooling duct comprises an elongated region, in particular with rectangular geometry, which extends along the longitudinal direction, particularly defined by a straight line. An inlet opening and/or outlet opening can in this case be formed by open sides of the depression and/or by openings in the bottom plate and/or top plate. A cooling fluid flow of a cooling fluid can flow through the cooling duct in the longitudinal direction from the inlet opening to the outlet opening. The at least one turbulator is arranged within a turbulator section of the cooling duct. In particular, the turbulator is arranged between the top plate and the top plate. Upstream and/or downstream of the turbulator section, at least one, in particular local, tapered portion of a flow cross-section of the cooling duct is configured to deflect a part region of the cooling fluid flow close to the edge within the cooling duct.

Preferably, the turbulator extends completely through the cooling duct between the bottom plate and a region of the depression in the top plate parallel to the bottom plate, in particular such that the turbulator adjoins the bottom plate and the region of the depression in the top plate parallel to it.

The bottom plate and the top plate can, e.g., adjoin one another in sections. Alternatively, an intermediate layer can be arranged between the bottom plate and the top plate.

In particular, the bottom plate and the top plate are connected to each other by means of a hard solder joint.

In other words, the cooling duct upstream and/or downstream of the turbulator section is narrowed by the tapered portion, particularly locally, so that flow lines of cooling fluid at the edge of the cooling duct are deflected by this tapered portion and cannot continue straight through the cooling duct. Due to this deflection, the tapered portion causes the cooling fluid flow close to the edge to slow down. In particular, an additional pressure drop in the part region of the cooling fluid flow close to the edge is created as a result. As a result, a bypass flow next to the turbulator, i.e. at the edge of the cooling duct, is able to be reduced. Such a bypass flow can be present, for example, in a bypass region in relation to the longitudinal direction next to the turbulator and between the turbulator, top plate and bottom plate. For example, a manufacturing-related demolding geometry of the top plate, which comprises radii and/or slopes, is situated in this bypass region. In particular, due to the demolding geometry of the top plate, the turbulator cannot fill the entire flow cross-section of the cooling duct, which means that a part region of the cooling fluid flow, namely the bypass flow, can flow past the turbulator. By tapering the cooling duct, this bypass flow is slowed down by the additional deflection or a pressure loss is generated in the bypass flow, so that a smaller volume flow flows past the turbulator and a larger volume flow flows through the turbulator instead. The tapered portion offers a particularly simple and cost-effective means of reducing the bypass flow.

Preferably, the tapered portion is configured such that a minimum width of the flow cross-section in the tapered portion is less than a width of the turbulator. In this context, the term “width” is considered to be a dimension in a direction perpendicular to the flow direction or the longitudinal direction and in a direction parallel to a sheet plane of the bottom plate. In particular, the minimum width of the flow cross-section in the tapered portion is at most 90%, preferably at most 80%, of the maximum width of the turbulator. As a result, a significant deflection of the part region of the cooling fluid flow close to the edge is reliably ensured in order to achieve a particularly effective reduction of the bypass flow.

The tapered portion is preferably formed by at least one projection of a wall delimiting the cooling duct. In particular, the bottom plate and the top plate are considered to be the walls delimiting the cooling duct. This enables a particularly simple and cost-effective design of the cooling device, as no additional components are required, for example.

Preferably, the projection is formed by a bead of the top plate, which in particular is essentially orthogonal to the longitudinal direction and projects from one edge of the cooling duct into the cooling duct. The tapered portion can be produced particularly easily and cost-effectively using one or more beads in the top plate. For example, the bead can already be produced by the deep-drawing process of the top plate.

The tapered portion is preferably arranged directly adjacent to the turbulator in the longitudinal direction. This ensures a particularly good taper effect, as a particularly strong deflection is achieved by avoiding free cross-sections between the turbulator and the tapered portion.

The tapered portion is preferably symmetrical with respect to the longitudinal direction. This means that the tapered portion is achieved in particular by narrowing the flow duct on both sides, for example opposite the flow direction.

The tapered portion is also preferably configured in such a way that the flow cross-section of the cooling duct in the region of the tapered portion is at least 5%, in particular a maximum of 20%, smaller than the flow cross-section of the cooling duct in the turbulator section in order to reliably provide sufficient deflection.

Preferably, the cooling device comprises a plurality of turbulators arranged in the cooling duct in succession along the longitudinal direction. For example, the turbulators can be configured to be identical or, alternatively, to differ from one another.

Particularly preferably, the cooling device comprises a tapered portion between two turbulators arranged one behind the other in the longitudinal direction. In particular, this results in multiple deflections of the streamlines of the cooling fluid flow close to the edge, so that a particularly effective reduction of the bypass flow can be achieved.

Preferably, the plurality of turbulators feature increasing turbulence factors along the longitudinal direction. The term “turbulence factor” is in particular considered to be turbulent swirling in the cooling fluid flow caused by the turbulator. For example, a turbulator can comprise a plurality of turbulence plates, each of which is inclined at a predefined turbulence angle to the flow direction. For example, a first turbulence angle of a first turbulator in the flow direction can be 10°, wherein in particular a second turbulence angle of a second turbulator can be 15°, and, e.g., a third turbulence angle of a third turbulator can be 20°. A particularly high cooling effect of the cooling device can be achieved as a result.

The tapered portion is also preferably formed by a first blocking element, which is preferably configured as an additional component to the bottom plate and top plate. In particular, the blocking element can be an insert, for example a cuboid, which is inserted into the cooling duct between the top plate and the bottom plate and causes the flow cross-section to tapered portion. This enables simple production with flexible adaptability of the tapered portion to different cooling duct geometries.

Preferably, the cooling device also comprises at least one second blocking element, which is arranged next to the turbulator with respect to the longitudinal direction, and in particular between the turbulator, top plate and bottom plate. The second blocking element can at least partially block the bypass flow directly or reduce a bypass cross-section. This makes it possible to further increase the efficiency of the cooling device.

The invention further relates to an electronic arrangement comprising the described cooling device and at least one electronic component that is being cooled. The electronic component being cooled is preferably a power module of a power electronics unit. The electronic arrangement is in particular a power electronic component, e.g. an inverter. The highly efficient cooling device can also enable a particularly high efficiency and longevity for the electronic component.

Preferably, the electronic component being cooled is connected to the bottom plate of the cooling device in a thermally conductive manner, e.g. by means of a copper layer. In particular, the electronic component is arranged on the bottom plate in the region of the turbulator, i.e., opposite to the turbulator on the bottom plate. Preferably, multiple electronic components that are being cooled can be arranged on the bottom plate for each turbulator.

### BRIEF DESCRIPTION OF THE DRAWINGS

The invention is described below based on exemplary embodiments in connection with the figures. In the figures, functionally identical components are respectively denoted by identical reference signs. Shown are:

FIG. 1 a view of a cooling device according to a first exemplary embodiment of the invention,

FIG. 2 a sectional view of an electronic arrangement with the cooling device in FIG. 1, and

FIG. 3 a view of a cooling device according to a second exemplary embodiment of the invention.

### DETAILED DESCRIPTION

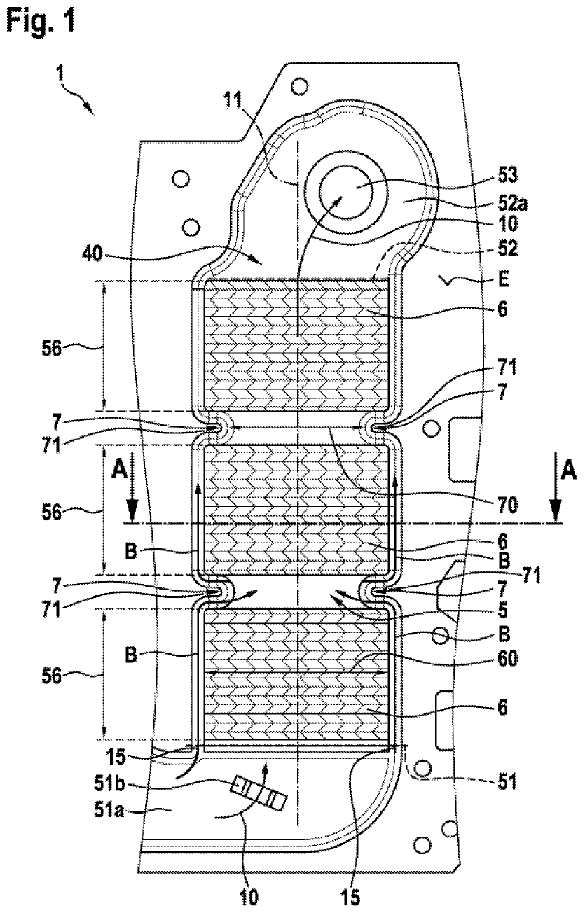

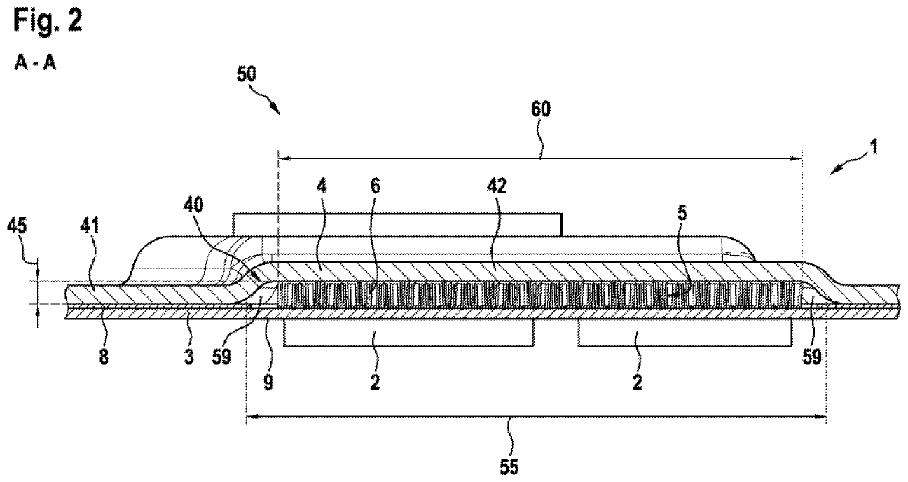

FIG. 1 shows a cooling device 1 according to a first exemplary embodiment of the invention. In FIG. 2, a sectional view of an electronic arrangement 50 comprising the cooling device 1 in FIG. 1 is shown along the section line A-A.

The cooling device 1 comprises a bottom plate 3 and a top plate 4. In FIG. 1, the cooling device 1 is shown without the bottom plate 3 for the sake of clarity.

The bottom plate 3 and top plate 4 are each made of a metal, preferably aluminum.

The bottom plate 3 is configured as a straight flat plate.

The top plate 4 is configured as a deep-drawn component which comprises a depression 40. In particular, the depression 40 is formed in that flat plate sections 41, 42 of the top plate 4 are arranged parallel to each other and corresponding upper sides are arranged at a predefined distance 45 from each other (see FIG. 2).

The bottom plate 3 and top plate 4 are arranged together so that a cooling duct 5 is formed between the bottom plate 3 and top plate 4 by the depression 40. In particular, the bottom plate 3 and the first plate section 41 of the top plate 4 are in this case connected to each other by means of a hard solder connection.

An intermediate plate 8 can be arranged between the bottom plate 3 and top plate 4, as shown in FIG. 2. For example, the intermediate plate 8 can provide an additional distance to an upper side of the top plate 4 in order to adjust a height of the cooling duct 5. Alternatively, the bottom plate 3 and first plate section 41 of the top plate 4 can also adjoin one another directly.

The depression 40, and thus the cooling duct 5, can be elongated with respect to a plane E of the top plate 4, in particular at least in sections having a rectangular shape (see FIG. 1).

The cooling duct 5 extends at least in sections, in particular symmetrically, along a longitudinal direction 11, which is in particular configured as a straight line.

The cooling duct 5 also extends at least from an inlet opening 51 to an outlet opening 52 and a cooling fluid flow can flow through it along the longitudinal direction 10 from the inlet opening 51 to the outlet opening 52.

The inlet opening 51 and the outlet opening 52 are each defined as cross-sections of the cooling duct 5 in a cross-sectional plane perpendicular to plane E at the beginning and end of the rectangular region.

In particular, the cooling duct 5 can comprise an inlet region 51a leading to the inlet opening 51 and an outlet region 52a connecting to the outlet opening 52. An outlet opening 53 is provided in the outlet region 52a, through which the cooling fluid flow can exit the cooling device 1.

The inlet region 51a can be arranged inclined with respect to the rectangular region of the cooling duct 5, as shown in FIG. 1. For example, a deflection element 51b can be provided in the inlet region 51a to deflect a direction of the cooling fluid flow towards the inlet opening 51.

The cooling device 1 further comprises a total of three turbulators 6, which are arranged within the cooling duct 5. Each turbulator 6 is in this case arranged in a turbulator section 56 extending along the longitudinal direction 11.

Each turbulator 6 can, e.g., feature a rectangular cross-section as seen from above (as in FIG. 1), wherein its width 60 transverse to the flow direction 10 is, e.g., greater than its length along the flow direction 10.

The cooling device 1 is provided for cooling electronic components 2, e.g. for power electronic devices, such as inverters. FIG. 2 shows a corresponding electronic arrangement 50 comprising the cooling device 1 and a plurality of electronic components 2.

The electronic components 2 are connected to the bottom plate 3 in a thermally conductive manner. To improve the conduction of heat, a copper coating 9 can, e.g., be provided between the bottom plate 3 and electronic components 2.

The electronic components 2 are arranged within or in the region of the turbulator sections 56 when viewed along the plane E of the top plate 4 (see FIG. 1).

Each turbulator 6 comprises a plurality of turbulence plates arranged inclined with respect to the longitudinal direction 11 in order to turbulently swirl the cooling fluid flowing through the cooling duct 5. This allows heat to be dissipated particularly effectively from the electronic components 2.

Preferably, each turbulator 6 has turbulence plates which are arranged at the same angle with respect to the longitudinal direction 11. Particularly preferably, the turbulators 6 each comprise turbulence plates at a greater angle with respect to the longitudinal direction 11 along the flow direction 10. In other words, the turbulators 6 each feature higher turbulence factors in the flow direction 10. As a result, the best possible heat dissipation from the electronic components 2 by means of the cooling fluid can still be achieved, even using the turbulators 6 located further downstream, where the heat transfer from the electronic components 2 results in a higher cooling fluid temperature than using the turbulators 6 located further upstream.

To achieve the highest possible cooling efficiency, as much of the flow cross-section of the cooling duct 5 as possible is covered by the turbulator 6. Given that the top plate 4 is a deep-drawn component, a demolding slope and radii on the edge of the depression 40 are required for the demolding process during deep drawing. Since the turbulators 6 have rectangular cross-sections, there are bypass regions 59 at the edge of the flow duct 5 to the side of the turbulators 6, i.e. between the turbulators 6, the top plate 4 and the bottom plate 3, in which no turbulent swirling of the cooling fluid flow occurs (see FIG. 2).

In order to keep a bypass flow 15 through the bypass regions 59 as low as possible and thus to be able to provide the highest possible cooling effect of the cooling device 1, tapered portions 7 of the flow cross-section of the cooling duct 5 are provided between the turbulator sections 56. The tapered portions 7 cause herein deflections of part regions of the cooling fluid flow close to the edge, as indicated by arrows B in FIG. 1. These deflections cause a deceleration, and thus a pressure drop in the part regions of the cooling fluid flow close to the edge, thereby reducing the volume flow passing through the bypass regions 59.

The tapered portions 7 are herein in the form of beads of the top plate 4, which are arranged on the edge of the depression 40. In other words, the tapered portions 7 are in the form of projections extending laterally into the cooling duct 5, which extend in particular over the entire height of the cooling duct 5 in a direction perpendicular to the plane E.

A minimum width 70 of the flow cross-section in the tapered portions 7 is herein less, preferably 10% less, than a width 60 of the turbulator 6. As a result, turbulators 6 and tapered portions undercut each other when viewed along the flow direction 10, forcing a particularly reliable flow deflection at the edge of the cooling duct 5.

The tapered portions 7 are configured symmetrically with respect to the longitudinal direction 11, as can be seen in FIG. 1. In other words, two tapered portions 7 are in each case configured opposite one another at the edges of the cooling duct 5.

The two opposing tapered portions narrow the flow cross-section of the cooling duct 5 in this region, such that the flow cross-section is at least 5% smaller than the total flow cross-section of the cooling duct 56 within one of the turbulator sections 56. In this context, the expression total cross-section between the top plate 4 and the bottom plate 3 is considered to be the total flow cross-section.

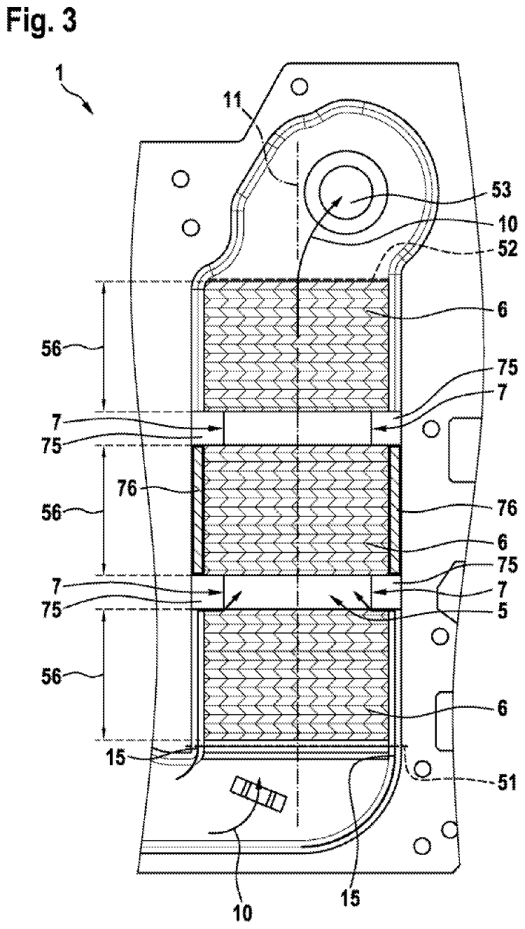

FIG. 3 shows a view of a cooling device 1 according to a second exemplary embodiment of the invention. The second exemplary embodiment essentially corresponds to the first exemplary embodiment of FIG. 1, with the difference that the tapered portions 7 are formed by first blocking elements 75 instead of by beads of the top plate 4. The first blocking elements 75 are cuboid inserts, or at least partially adjusted to the demolding geometry of the top plate 4, which are arranged at the edge of the cooling duct 5 and between the turbulator sections 56. Turbulators 6 and blocking elements 75 are arranged directly adjacent to each other in the longitudinal direction 11.

In addition, in the second exemplary embodiment of FIG. 3, second blocking elements 76 are provided, which are arranged next to the central turbulator 6 with respect to the longitudinal direction 11. The second blocking elements 76 can also be provided as additional inserts. This allows the bypass flow 15 to be further reduced. As an alternative to the variant shown in FIG. 3, second blocking elements 76 can preferably be arranged next to all turbulators 6.

1. A cooling device for cooling electronic components (2), comprising:
a bottom plate (3),
a top plate (4) which is a deep-drawn component with a depression (40),
wherein the bottom plate (3) and the top plate (4) are arranged in such a way that a cooling duct (5) is formed between the bottom plate (3) and the top plate (4) by way of the depression (40)
wherein the cooling duct (5) extends along a longitudinal direction (11) from an inlet opening (51) to an outlet opening (52),
wherein a cooling fluid flow of a cooling fluid can flow through the cooling duct (5) along the longitudinal direction (11); and
at least one turbulator (6) which is arranged within a turbulator section (56) of the cooling duct (5),
wherein at least one tapered portion (7) of a flow cross section of the cooling duct (5) is configured upstream and/or downstream of the turbulator section (56), in order to deflect a part region, close to the edge, of the cooling fluid flow within the cooling duct (5).

2. The cooling device according to claim 1, wherein the tapered portion (7) is configured such that a minimum width (70) of a flow cross-section in the tapered portion (7) is smaller than a width (60) of the at least one turbulator (6).

3. The cooling device according to claim 1, wherein the tapered portion (7) is formed by at least one projection (71) of a wall delimiting the cooling duct (5).

4. The cooling device according to claim 3, wherein the projection (71) is formed by a bead of the top plate (4).

5. The cooling device according to claim 1, wherein the tapered portion (7) is arranged directly adjacent to the at least one turbulator (6) with respect to the longitudinal direction (11).

6. The cooling device according to claim 1, wherein the tapered portion (7) is configured symmetrically with respect to the longitudinal direction (11).

7. The cooling device according to claim 1, wherein the tapered portion (7) is configured such that the flow cross-section of the cooling duct (5) in a region of the tapered portion (7) is at least 5% smaller than the flow cross-section of the cooling duct (5) in the turbulator section (56).

8. The cooling device according to claim 1, comprising a plurality of turbulators (6) which are arranged one behind the other in the cooling duct (5) along the longitudinal direction (11).

9. The cooling device according to claim 8, comprising in each case a tapered portion (7) between two turbulators (6) arranged one behind the other in the longitudinal direction (11).

10. The cooling device according to claim 8, wherein the turbulators (6) have increasing turbulence factors along the longitudinal direction (11).

11. The cooling device according to claim 1, wherein the tapered portion (7) is formed by a first blocking element (75), which is configured in particular as an additional component to the bottom plate (3) and top plate (4).

12. The cooling device according to claim 1, further comprising at least one second blocking element (76) arranged next to the turbulator (6) with respect to the longitudinal direction (11).

13. An electronic arrangement comprising:
a cooling device (1) according to claim 1, and
at least one electronic component (2) that is to be cooled.

14. The electronic arrangement according to claim 13, wherein the electronic component (2) being cooled is connected to the bottom plate (3) of the cooling device (1) in a thermally conductive manner.

15. The cooling device according to claim 7, wherein the tapered portion (7) is configured such that the flow cross-section of the cooling duct (5) in the region of the tapered portion (7) is a maximum of 20% smaller than the flow cross-section of the cooling duct (5) in the turbulator section (56).

16. The cooling device according to claim 9, wherein the turbulators (6) have increasing turbulence factors along the longitudinal direction (11).

17. The cooling device according to claim 11, further comprising at least one second blocking element (76) arranged next to the turbulator (6) with respect to the longitudinal direction (11).
